(19) United States
(12) Patent Application Publication
(10) Pub. No.: US 2026/0095022 A1
(43) Pub. Date: Apr. 2, 2026

(54) HYBRID SILICON III-V OPTICAL DEVICES WITH A HIGH REFRACTIVE INDEX SPACER BETWEEN GAIN MEDIUM AND WAVEGUIDE

(71) Applicant: Intel Corporation, Santa Clara, CA (US)

(72) Inventors: Sergei Sochava, Sunnyvale, CA (US); Amit Mizrahi, San Jose, CA (US); Richard Jones, San Mateo, CA (US); Pierre Doussiere, Santa Clara, CA (US)

(73) Assignee: Intel Corporation, Santa Clara, CA (US)

(21) Appl. No.: 18/900,497

(22) Filed: Sep. 27, 2024

(51) Int. Cl. H01S 5/026; H01S 5/343

(52) U.S. Cl. CPC H01S 5/026; H01S 5/3434

(57) ABSTRACT

Active hybrid silicon optical device structures including a silicon optical waveguide and a III-V semiconductor material stack further includes a high refractive index spacer located between the silicon waveguide and a III-V gain material. The spacer may be undoped or doped (e.g., n-type). The spacer may have a composition unique from the III-V semiconductor material stack or the spacer may have substantially the same composition as one or more other material layers of the III-V semiconductor stack. In exemplary embodiments, the spacer has a refractive index of at least 3.0 and a layer thickness of at least 0.3 μm. In laser structures, the spacer locates peak power of the resonant mode farther from the optical gain material and/or doped material having high optical loss. Along with reducing modal losses, mode area is increased, reducing photon density and improving laser reliability. In SOA structures, greater mode area may increase saturation power.

### BACKGROUND

Photonic integrated circuits (PICs) are increasingly important in high-performance computing, data center, and cloud computing applications. The use of silicon in photonics (SiPh), enables high-volume, low-cost and highly integrated PICs. The provisioning of on-chip active optical devices, such as lasers, is a critical path in PIC development, particularly for applications relying on dense wavelength division multiplexing (DWDM). Along with lower manufacturing costs, the integration of active optical devices directly on silicon would reduce coupling losses for SiPh applications.

A “hybrid silicon” active optical device heterogeneously integrates III-V material with a silicon substrate comprising an optical waveguide. Active optical devices include an optical gain medium with some examples including lasers and semiconductor optical amplifiers (SOAs). For hybrid optical device architectures, the gain (active) material may be in the form of quantum dot structures or quantum well layers, for example.

Coherent communication and Frequency Modulated Continuous Wave (FMCW) LIDAR systems benefit from narrow linewidth laser sources and SOAs providing high optical power. Hybrid integration of distributed-feedback (DFB) lasers with silicon PIC (SiPh) provides compact low-cost solutions, but optical power may be too low and/or linewidth too wide for some applications. High power SOAs are also a challenging design element since output power is limited by semiconductor gain saturation.

Hybrid silicon active optical device architectures that can improve laser power, reduce linewidth, and/or improve SOA power would therefore be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram of methods for fabricating a hybrid silicon optical device, in accordance with some embodiments;

FIG. 2A is a cross-sectional profile view of an active III-V P-i-N diode structure over a spacer, in accordance with some embodiments;

FIG. 2B is an expanded cross-sectional profile view of the spacer introduced in FIG. 2A, in accordance with some embodiments;

FIG. 2C is an expanded cross-sectional profile view of the spacer introduced in FIG. 2A, in accordance with some alternative embodiments;

FIG. 3A is a plan view of a silicon PIC substrate, in accordance with some embodiments;

FIG. 3B is a cross-sectional profile view of a silicon PIC substrate, in accordance with some embodiments;

FIG. 4-5 are cross-sectional profile views illustrating formation of a hybrid silicon structure evolving during practice of the methods shown in FIG. 1, in accordance with some embodiments;

FIG. 6A illustrates a plan view of a hybrid silicon optical device, in accordance with some embodiments;

FIG. 6B illustrates a cross-sectional profile view of the hybrid silicon optical device shown in FIG. 6A, in accordance with some further embodiments;

FIG. 7 illustrates a cross-sectional view showing an optical mode profile of a hybrid silicon active optical device including a spacer, in accordance with some further embodiments;

FIG. 8 illustrates a cross-sectional view showing an optical mode profile of a hybrid silicon active optical device lacking a spacer;

FIG. 9 illustrates a mobile computing platform and a data server machine comprising a silicon PIC including a plurality of hybrid silicon optical devices, in accordance with some embodiments; and

FIG. 10 is a functional block diagram of an electronic computing device, that may implement one or more of the components of the mobile platform or data server machine illustrated in FIG. 9, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The inventors have found that for hybrid silicon III-V active optical devices a larger, lower-loss, optical mode can be achieved by introducing a thick spacer of high-index semiconductor material between an overlying III-V active P-i-N material stack and underlying silicon optical waveguide. The high index semiconductor may be, for example, doped or undoped III-V material. Alternatively, the high index semiconductor material may be amorphous silicon (α-Si).

According to embodiments herein, active hybrid silicon optical device structures including a silicon optical waveguide and a III-V semiconductor material stack further comprise a high refractive index spacer located between the silicon waveguide and the active P-i-N structure. A hybrid silicon III-V optical device including a thick spacer in accordance with embodiments may reduce intrinsic laser loss by moving the optical mode center away from gain material and p-doped material. The thick spacer may also increase mode size, enabling higher Q cavity designs. For embodiments where the center of the resonant mode is located within the high-index spacer material, a high-Q laser cavity can generate higher power narrow-linewidth light emission. Incorporation of a thick spacer of high-index III-V material may also benefit hybrid silicon III-V SOAs, for example enabling them to achieve higher saturation power.

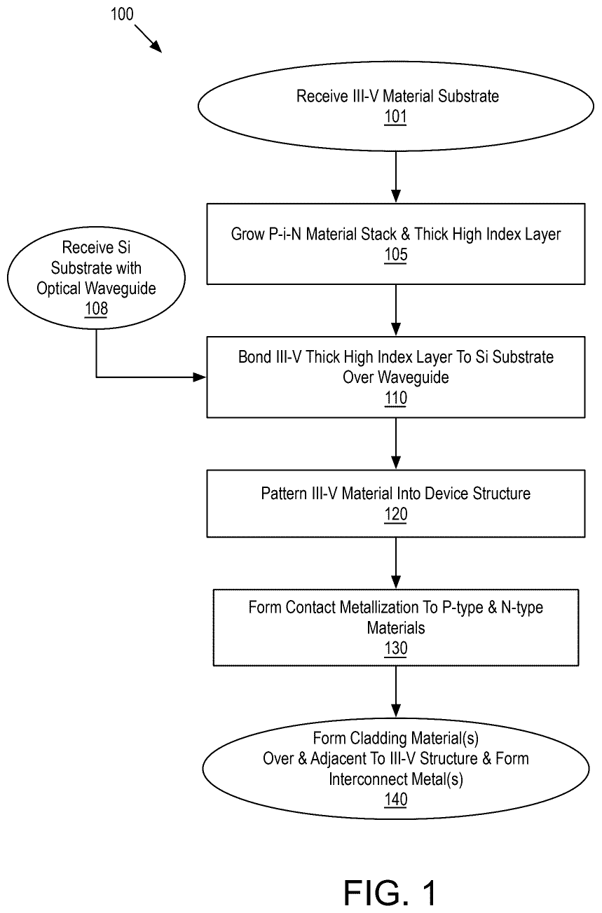

FIG. 1 is a flow diagram of methods 100 for fabricating a hybrid silicon active optical device, such as an SOA or laser, in accordance with some embodiments. Methods 100 may be practiced, for example, to fabricate a hybrid silicon quantum dot laser (HSQDL) having one or more of the structural attributes described herein. Methods 100 may also be practiced to fabricate other hybrid silicon devices, such as a quantum well laser (HSQWL) or a semiconductor optical amplifier. In some exemplary embodiments, methods 100 integrate an HSQDL or HSQWL within one or more photonic integrated circuits (PICs), and more specifically within one or more silicon photonic chips. Although many examples are further described in the context of laser and SOA implementations, the exemplary architectures may instead be applied to alternative hybrid silicon optical devices, such as, photo detectors or modulators.

Methods 100 being at input 101 a donor substrate, for example comprising a III-V material, is received. The donor substrate received at input 101 may be any substrate suitable for epitaxially growing additional III-V material. In some examples, the donor substrate received includes monocrystalline binary GaAs. In some other examples, the donor substrate received includes monocrystalline binary InP. In some other examples, the donor substrate received includes monocrystalline sapphire. The donor substrate may be a bulk monocrystalline material or include some other form of mechanical support.

Methods 100 continue at block 105 where a III-V P-i-N material stack is epitaxially grown. Any known epitaxial process may be practiced at block 105, such as, but not limited to, molecular beam epitaxy (MBE) or metal organic chemical vapor deposition (MOCVD). In exemplary embodiments, a high index spacer material is epitaxially grown on the P-i-N material stack. Alternatively, a high index spacer material is otherwise deposited upon the P-i-N material stack, for example by a CVD.

The P-i-N material stack grown at block 105 is advantageously substantially monocrystalline and may have any number of material layers. In exemplary embodiments, the P-i-N material stack is active and comprises gain material, such as multiple quantum well (MQW) material layers or quantum dot (QD) material structures. The gain material(s) may have any chemical composition(s) and a micro/nano structure known to be suitable as MQW or QD optical gain material within one or more bands of the electromagnetic energy spectrum.

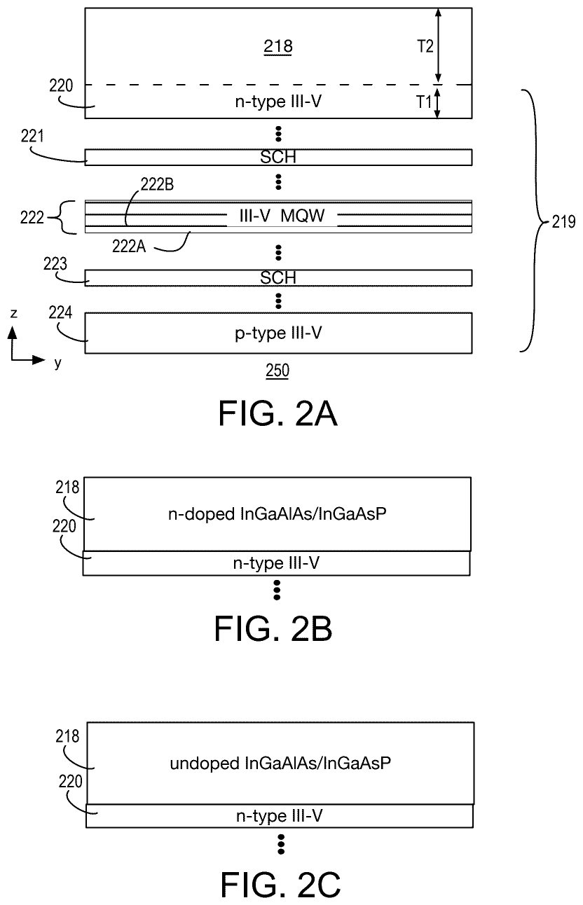

FIG. 2A illustrates a cross-sectional profile view of a III-V P-i-N material stack 219 that may be grown on a seeding surface of a donor substrate 250. In accordance with some embodiments, material layers of P-i-N material stack 219 all comprise a Group III-V crystalline alloy material (i.e., a III-V material stack). As shown, material stack 219 includes a stacked P-i-N diode structure comprising at least one optical gain material layer 222, in accordance with some embodiments. Gain material layer 222 is between an n-type material 220 and a p-type material 224. Material stack 219 is advantageously an epitaxial heterostructure that may have any number of gain material layers (represented by ellipses) between n-type material 220 and p-type material 224. Each optical gain material layer 222 may have any thickness, with 10-50 nm being an exemplary thickness range.

In some examples, optical gain material layer 222 comprises multiple quantum well (MQW) layers 222A and 222B of different III-V alloy compositions and different optical band offsets and/or lattice mismatch. In other examples optical gain material layer 222 comprises quantum dots of a first III-V composition, and a shell material another III-V alloy having a distinct chemical composition with a suitable optical band offset and/or lattice mismatch with that of quantum dots. The chemical composition of layers or structures within gain material layer 222 may be varied over a range of binary, ternary or quaternary III-V alloys, layer thicknesses, and/or nanostructure dimensions. In some embodiments optical gain material layer 222 is suitable for optical gain within a particular energy band (e.g., IR band of 1270 nm-1330 nm),
N-type material 220 and p-type material 224 may comprise one or more electrically active impurity dopants, which may vary with the majority constituents of materials 220, 224. For example, in some embodiments where materials 220 and 224 are both ternary or quaternary alloys including Ga and As (e.g., InGaAsP) n-type material 220 may comprise carbon, beryllium, magnesium, zinc, or cadmium while p-type material 224 may comprise silicon, tellurium or carbon. Electrically active impurity dopant concentrations may vary with implementation to achieve any bulk electrical resistivity suitable for the application. Layer thicknesses of material 220, 224 may also vary to achieve as sufficiently low external electrical resistance associated with the electrical resistivity of the impurity doped material and a metal-semiconductor junction (contact) resistance. Thickness T1 may therefore vary by 100 nm, or more, as a function of active donor impurity concentration(s) possible for a given III-V alloy. In some exemplary InGaAsP embodiments, layer thickness T1 is at least 100 nm. P-type material 224 may have a significantly greater layer thickness (e.g., 1-2 μm).

As further illustrated in FIG. 2A, P-i-N material stack 219 may further include separate confinement heterostructures (SCH) 221 and 223, located between gain material layer 222 and each of impurity-doped materials 220, 224. SCH 221 and/or SCH 223 may have any architecture known to be suitable for a particular active optical device and each may comprise a heterostructure including high refractive index material layers of varying optical index and/or band gap. In some examples, SCH 221 and 223 each comprises a quaternary III-V alloy, such as InGaAlAs and/or InGaAsP with significantly lower impurity dopant concentration than that of material layers 220, 224, respectively.

As further illustrated in FIG. 2A, a spacer 218 is over P-i-N material stack 219. In exemplary embodiments, spacer 218 is in direct contact with n-type III-V material 220. A dashed line is illustrated in FIG. 2A because, in some embodiments where n-type III-V material 220 has a first composition and spacer 218 has a second composition there may be a clear material interface between the two. However, in other embodiments where there is negligible composition variation, a clear material interface may not be as readily apparent.

Spacer 218 has a high refractive index, for example of at least 3.2 In some embodiments, spacer 218 has a refractive index in the range of 3.2-3.6 within the optical band of gain material 222 (e.g., 1310 nm). In some exemplary embodiments, spacer 218 is a III-V material. III-V materials with a suitable refractive index include binary InP, binary GaP, some of their ternary alloys, such as InAlAs, AlGaAs, and InGaP, and their quaternary alloys, such as InGaAsP, and InGaAlAs. In alternative embodiments, spacer 218 is other than a III-V material with a-Si (e.g., ˜3.5 at 1310 nm) being one example.

As shown in FIG. 2A, spacer 218 has a thickness T2, which is greater than thickness T1. Although thickness T2 may vary with implementation, in some examples thickness T2 is at least 0.25 μm, and advantageously at least 0.3 μm. In further examples, thickness T2 is no more than 0.5 μm. For embodiments where spacer 218 is a III-V alloy, the III-V alloy is advantageously one which has a sufficient lattice match with P-i-N material stack 219 to remain monocrystalline for thicknesses exceeding 0.25 μm. Of the above III-V alloys, InGaAsP or InGaAlAs may therefore be advantageous materials for spacer 218.

FIG. 2B is an expanded cross-sectional profile view of spacer 218, in accordance with some embodiments where the spacer material is impurity doped (e.g., with donor impurities). Impurity doping of spacer 218 may be advantageous to supplement n-type III-V material 220 (e.g., further reducing external resistance). Hence, for some embodiments where n-type III-V material 220 and spacer 218 have the same majority lattice constituents (e.g., both InGaAsP), n-type III-V material 220 and spacer 218 may also have the same impurities (e.g., donor species) and even the same impurity concentration. However, in other embodiments where n-type III-V material 220 and spacer 218 do not have the same majority lattice constituents (e.g., one being InGaAsP and the other being InGaAlAs, etc.), the donor concentrations may, or may not, also vary between n-type III-V material 220 and spacer 218.

FIG. 2C is an expanded cross-sectional profile view of spacer 218, in accordance with some alternative embodiments where the spacer material is substantially undoped (e.g., intrinsic) in the recognition that spacer 218 need not be impurity doped to adequately function as a spacer. Hence, for some embodiments where n-type III-V material 220 and spacer 218 have the same majority lattice constituents (e.g., both InGaAsP), the donor impurities in n-type III-V material 220 may be absent from spacer 218, or at least in a concentration that is an order of magnitude, or more, lower than that of n-type III-V material 220. In other embodiments where n-type III-V material 220 and spacer 218 do not have the same majority lattice constituents (e.g., one being InGaAsP and the other being InGaAlAs, etc.), the donor impurity concentration within spacer 218 is additionally at least an order of magnitude lower than that of n-type III-V material 220.

Returning to FIG. 1, methods 100 continue with receiving a silicon substrate at input 108. The substrate received at input 108 includes at least one optical waveguide that has been fabricated upstream of methods 100 according to any technique(s) known in the art. The substrate may further comprise one or more other passive optical devices, such as (de)multiplexers, grating couplers, etc. The substrate may also comprise active components such as modulators and/or photodetectors. Such optical devices may have been fabricated into the substrate upstream of methods 100 according to any technique(s) known in the art. Such optical devices may also be fabricated downstream of methods 100.

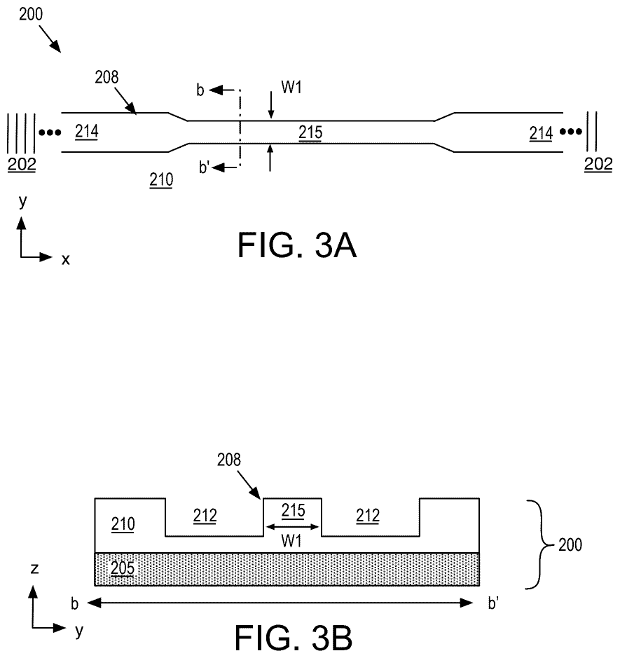

FIG. 3A is a plan view of a monolithic silicon PIC substrate 200, in accordance with some laser embodiments. FIG. 3B is a cross-sectional profile view of silicon PIC substrate 200 through the b-b′ plane demarked by the dot-dashed line in FIG. 3A, in accordance with further embodiments. In some examples, substrate 200 is a workpiece having a diameter of at least 300 mm but may also be of any other dimension(s). Substrate 200 includes a substantially planar optical waveguide 208 patterned within a substrate material layer 210 or within a thin film on substrate material layer 210. In exemplary embodiments where substrate material layer 210 comprises substantially monocrystalline silicon, waveguide 208 is also substantially monocrystalline silicon. In other embodiments, waveguide 208 is predominantly silicon and nitrogen (e.g., Si₃N₄). In some examples illustrated by FIG. 3B, substrate material layer 210 is a top layer of a semiconductor-on-insulator (SOI) substrate material stack further comprising an insulator material layer 205. In exemplary embodiments, where substrate material layer 210 is substantially pure silicon, insulator material layer 205 is advantageously predominantly silicon and oxygen (e.g., SiO₂). One or more additional substrate material layers (not depicted) may be under, or on a back side of, insulator material layer 205. In some SOI embodiments, insulator material layer 205 is on a bulk layer of substantially pure (mono)crystalline silicon.

Optical waveguide 208 may have any suitable architecture, such as, but not limited to, a substantially planar ridge waveguide of the type having the profile illustrated in FIG. 3B. In some embodiments, a top surface of the silicon optical waveguide includes a central ridge (not depicted). In the examples further illustrated by FIG. 3A, optical waveguide 208 has a substantially constant transverse lateral width W1 (e.g., in y-dimension) over a longitudinal length (e.g., in x-dimension) of an active waveguide region 215. At opposite ends of active waveguide region 215, waveguide 208 tapers out to passive waveguide regions 214 having a larger transverse width. Although the active waveguide transverse lateral width W1 may vary, in some exemplary embodiments width W1 is in the range of 150 nm to 1 μm. A similar range is also applicable to the z-height (z-axis in FIG. 3B) of at least active waveguide region 215. Air 212 is over a surface of PIC substrate 200 and adjacent to sidewalls of waveguide 208.

Although implementations may vary, in laser devices at least a portion of optical waveguide 208 may comprise a mirror for establishing a resonant optical cavity within active waveguide region 215, for example according to any suitable Fabry-Perot (FP) laser architecture. In the illustrated embodiment, grating structures 202 are defined within passive waveguide regions 214, for example according to any suitable Distributed Bragg Reflector (DBR) laser architecture. In alternative architectures (e.g., a Distributed Feedback (DFB) laser architecture), one or more grating structures 202 may be located within active waveguide region 215. The illustrated mirror structures may be absent from other exemplary active optical device embodiments (e.g., SOAs) that may otherwise include all the structural features illustrated for a laser.

Returning to FIG. 1, methods 100 continue at block 110 where a material stack including the III-V P-i-N material stack and the optical mode spacer is transferred from the donor substrate received at input 101 to the PIC substrate received at input 108. In exemplary embodiments, the spacer is directly bonded to a to a host substrate surface comprising silicon. Any substrate (wafer)-level film bonding process may be practiced at block 110 to form a hybrid material heterostructure. The term “hybrid” is in reference to resulting structure including non-silicon (e.g., III-V) material layers bonded to underlying silicon (or a silicon-based thin film material layer thereon). Once bonded, the donor substrate may be removed to complete transfer of the P-i-N material stack and the optical mode spacer.

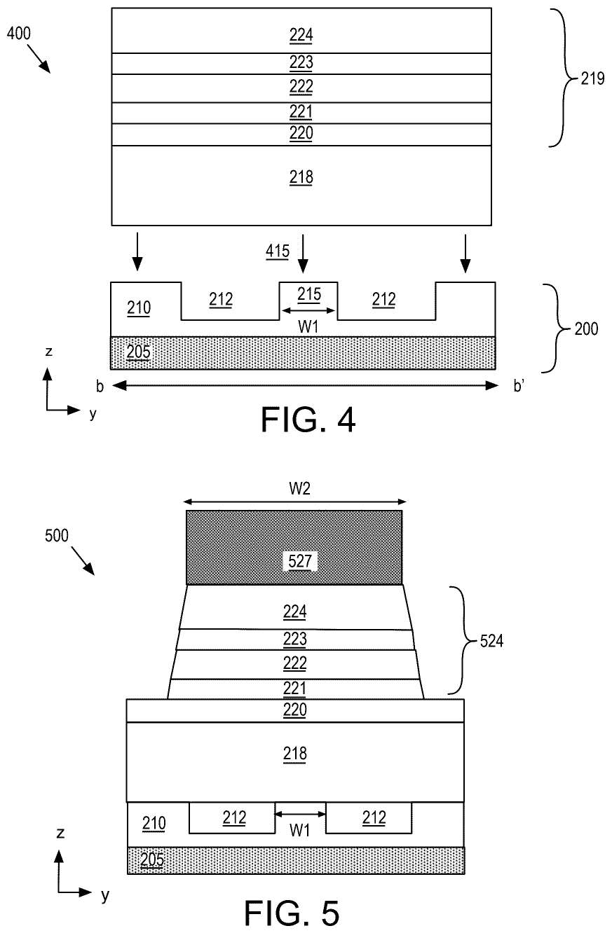

FIG. 4 is a cross-sectional profile view illustrating formation of a HSQDL workpiece 400, in accordance with some embodiments where optical mode spacer 218 is bonded over PIC substrate 200. As shown, bonding process 415 places n-type material 220 proximal to optical waveguide 208 and p-type material 224 distal from waveguide 208. In the illustrated example, n-type material 220 spaced apart from waveguide active region 215 by the thickness of intervening spacer 218. Although spacer 218 may be in direct contact with a top surface of silicon waveguide active region 215, one or more intervening material layers (not depicted) be between spacer 218 and waveguide active region 215. In the illustrated example, both spacer 218 and P-i-N material stack 219 bridges over air 212 and extends over an adjacent (perimeter) portion of substrate material layer 210. However, other waveguide cladding structures are also possible.

Returning to FIG. 1, methods 100 continue at block 120 where at least some layers of the transferred P-i-N material stack are patterned into a structural feature. One or more dry or wet etch processes may be practiced at block 120, for example. In the embodiment further illustrated in FIG. 5 an HSQDL structure 500 has been defined from HSQDL workpiece 400 (FIG. 4). As shown in FIG. 5, a III-V mesa has a sidewall 524 that has been etched according to a patterned etch mask 527. As shown, p-type material 224, gain material 222, SCH 221 and SCH 223 have all been etched into a mesa structure having a minimum transverse lateral width W2. In the illustrated example, material layers 220 remain unpatterned following mesa definition. Mesa lateral width W2 is substantially centered over waveguide lateral width W1. In the illustrated example, mesa (top) width W2 is significantly greater than active optical waveguide transverse lateral width W1, for example because larger mesa width W2 may advantageously reduce the thermal resistance of HSQDL structure 500. In some embodiments mesa width W2 is 10 μm, or more. However, mesa width W2 may vary with implementation.

For some wide-mesa embodiments, electrical resistivity within at least one material layer of the mesa varies over width W2, for example to confine an electrical channel to a central portion of the wide mesa that is directly over the optical waveguide active region of width W1. In some embodiments, the electrical resistivity of p-type material 224 is lower over a central portion of the mesa, and higher proximal to mesa sidewall 524. In some embodiments, the electrical resistivity of a perimeter portion the p-type material 224 is increased by implanting one or more species, such as protons or helium ions, into the perimeter portion of p-type material 224. In some alternative embodiments, the mesa is patterned such that width W2 is only slightly larger (e.g., within 1-2 μm) than active optical waveguide width W1.

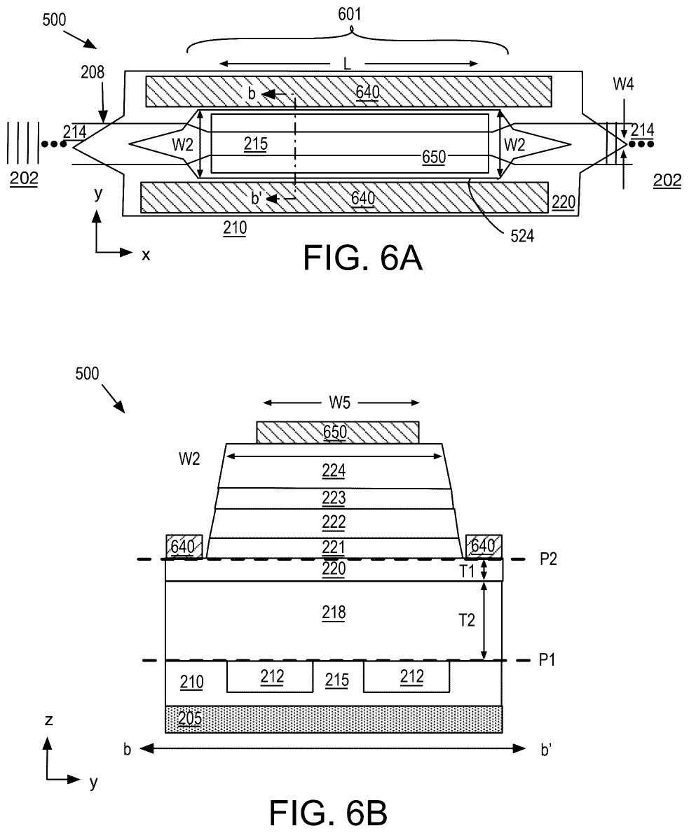

Returning to FIG. 1, methods 100 continue at block 130 where device contact metallization may be formed to complete an active optical device structure. For an exemplary III-V material mesa, a first contact (e.g., p-contact) metallization feature may be formed over a top surface of p-type material in a III-V mesa while a second contact (e.g., n-contact) metallization feature may be formed on n-type material adjacent to the III-V material mesa. FIG. 6A illustrates a plan view of a hybrid silicon optical device, in accordance with some embodiments. FIG. 6B illustrates a cross-sectional profile view of the hybrid silicon optical device along the b-b′ dot-dash line shown in FIG. 6A, in accordance with some further embodiments.

As shown, structure 500 comprises a mesa 601 of substantially constant width over a longitudinal length L. Length L may vary with implementation, for example from 100 μm to 2 mm, or more. At opposite ends of length L, the mesa width tapers from lateral width W2 to a first transverse tip width. N-type material 220 (and spacer 218) similarly taper from a greater width accommodating contact metallization 640 to a second transverse tip width W4. The illustrated III-V material tapers overlap a complementary taper in underlying silicon optical waveguides 208 and approximate an adiabatic taper. Although transverse tip width W4 may vary, in some examples tip width W4 is less than 0.4 μm, which is sufficient to ensure a fraction of optical power remaining within the III-V material mesa (i.e. not coupled into silicon waveguide 208) is less than 2% for embodiments where the spacer thickness is 0.3 μm. Although a width of 0.4 m is readily achievable with current photolithography and III-V etch technologies, width W4 may nevertheless be relaxed to greater widths (e.g., 0.5, 0.6 m, etc.) if somewhat lower coupling efficiency (e.g., 3-8%) is acceptable for a given application or if spacer thickness is reduced.

As shown in FIGS. 6A and 6B, a contact metallization feature 640 is in direct contact with n-type material 220 adjacent to mesa sidewall 524. Contact metallization feature 640 may have any chemical composition known to be suitable for an ohmic or tunneling electrical contact to n-type material 220. Another contact metallization feature 650 is in direct contact with p-type material 224. Contact metallization feature 650 may have any chemical composition known to be suitable for an ohmic or tunneling electrical contact to p-type material 224. As shown, contact metallization feature 650 has a lateral contact width W5 that is significantly greater than silicon waveguide width W1 and nearly equal to mesa lateral width W2. For example, contact width W5 may be 80%, or more, of mesa width W2. The larger width W5 may improve top side heat extraction over the larger mesa width W2. Within p-type material 224, an electrical channel width (not depicted) may be confined to be less than contact width W5. For embodiments where width W1 is less than 1 μm, channel width may be in the range of 2-6 μm, for example.

As further illustrated in FIG. 6B, a plane P1 coincident with a top surface of optical waveguide active region 215 is spaced apart from a parallel plane P2 coincident with a bottom surface of contact metallization feature 640 and/or a top surface of n-type material 220. In the illustrated embodiment, the spacing between planes P1 and P2 is equal to a sum of thicknesses T1 and T2. Accordingly, with thickness T1 being at least 0.1 μm, thickness T2 being at least 0.25 am, the sum of T1 and T2 is at least 0.35 μm. In further embodiments, the sum of thicknesses T1 and T2 is no more than 0.7 μm, for example where thickness T1 is no more than 0.2 μm and thickness T2 is no more than 0.5 μm.

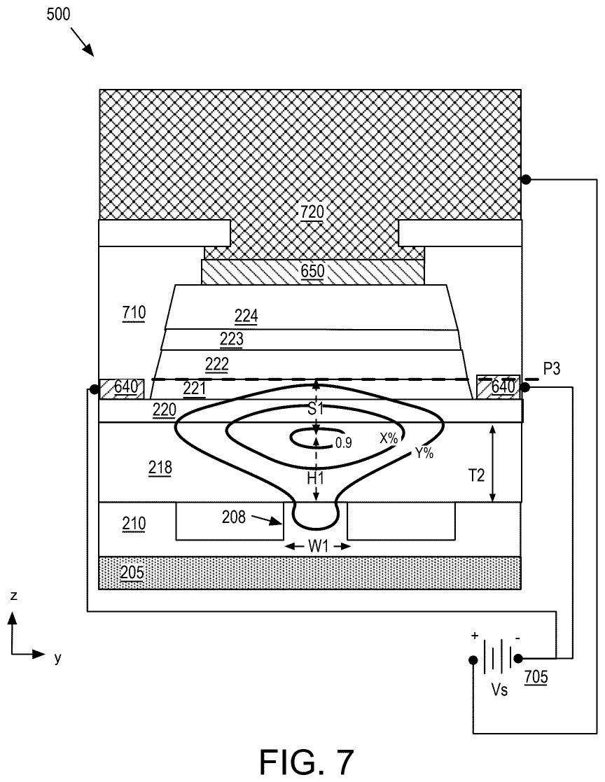

Returning to FIG. 1, HSQDL fabrication methods 100 end at output 140 where one or more cladding materials may be formed over the active optical device structure. Thick metal can be placed over one or more regions of the device, for example to further reduce the thermal resistance of the active optical structure. In some examples, the thick metal is electrically coupled to a contact metallization feature as both an electrical power supply rail and a topside laser heat dissipator. FIG. 7 illustrates a cross-sectional view of HSQDL structure 500 along a y-z plane defined by the b-b′ line illustrated in FIG. 6A following the formation of one or more cladding materials 710 and formation of interconnect metal 720. Cladding materials 710 may comprise any dielectric material (e.g., silicon-based) having suitable electrical and optical (e.g., refractive index) properties. Interconnect metal 720 is in direct contact with p-contact metallization 650. During device operation, one rail of a power supply 705 may be coupled to contact metallization feature 650 through interconnect metal 720. Another rail of power supply 705 may be coupled to contact metallization features 640.

Interconnect metal 720 may comprise one or more metals, such as, but not limited to, Al or Cu. In exemplary embodiments, interconnect metal 720 has a thickness (e.g., along z-axis) exceeding the electrical power delivery demands of HSQDL structure 500. For example, metal thickness may be 8-10 μm, or more, to enhance topside dissipation of heat extracted through the mesa interface area. Interconnect metal 720 may be further coupled to a package level thermal solution (not depicted), such as an external heat spreader and/or heat exchanger, etc.

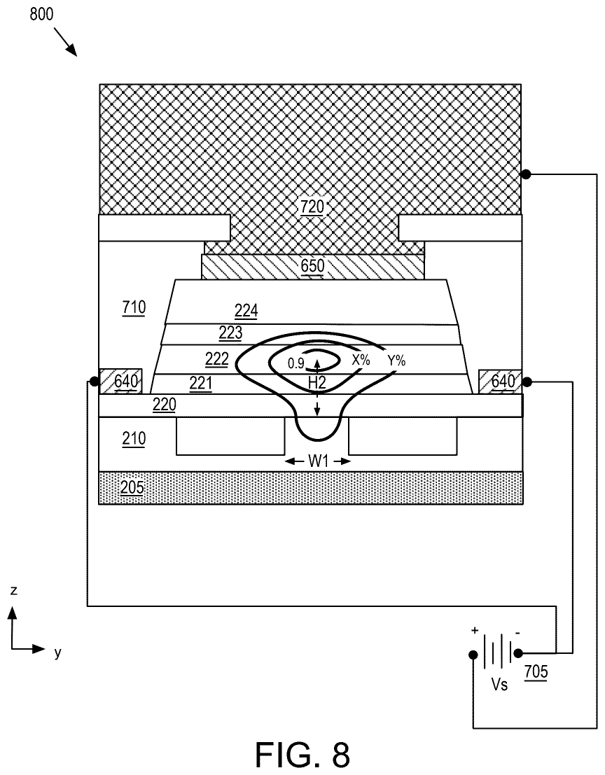

FIG. 7 further illustrates a profile of a resonant optical mode supported during the operation of a reference HSQDL structure 500. FIG. 8 illustrates a profile of a resonant optical mode supported during the operation of a comparative HSQDL structure 800, which includes all the features of the HSQDL structure 500 (FIG. 7) except for spacer 218.

In FIG. 7, the resonant mode profile has a peak power (e.g., of 1.0) located within III-V material located between III-V optical gain material 222 and a top surface (most proximate to gain material 222) of silicon optical waveguide 208. For the illustrated embodiment where spacer 218 is has a thickness T2 of at least 0.3 μm and an optical index of at least 3.2, peak optical power is at a height H1 from the top surface of silicon waveguide 208, which is within thickness T2. Accordingly, peak power is spaced a non-zero distance S1 from a plane P3 coincident with a nearest interface of overlying optical gain material 222. In exemplary embodiments distance S1 is at least 0.25 μm. As further illustrated, mode power over 0.9 is within spacer 218. Mode power drops to X % within n-type material 220 with only some lesser Y % power propagated within SCH 221.

In contrast, in FIG. 8 the mode profile has a peak power located at height H2, which is within III-V optical gain material 222. As further illustrated, mode power over 0.9 is confined within gain material 222. For HSQDL structure 800, mode power drops to X % within n-type material 220 as well as within SCH 223. Y % power is propagated within n-type material 220 as well as SCH 223.

Accordingly, in HSQDL structure 500 less than Y % power is confined within gain material 222 while peak power propagates within gain material 222 for HSQDL structure 800. Modal loss in HSQDL structure 500 attributable to gain material 222 should therefore be reduced (e.g., to less than one-half) from that of HSQDL structure 800. As further illustrated in FIG. 7-8, HSQDL structure 500 has an effective mode area that is larger than that of HSQDL structure 800. In some embodiments where spacer 218 is at least 0.3 μm and refractive index is at least 3.2, mode area is at least 3.3 μm² whereas in the absence of spacer 218, mode area is less than 2.4 μm². The greater mode area of HSQDL structure 500 may increase the catastrophic optical damage (COD) threshold and facilitate greater laser mirror reflectivity relative to HSQDL structure 800. Furthermore, for SOA structures including a similar spacer, the greater mode area associated with the addition of spacer 218 should permit higher saturation power.

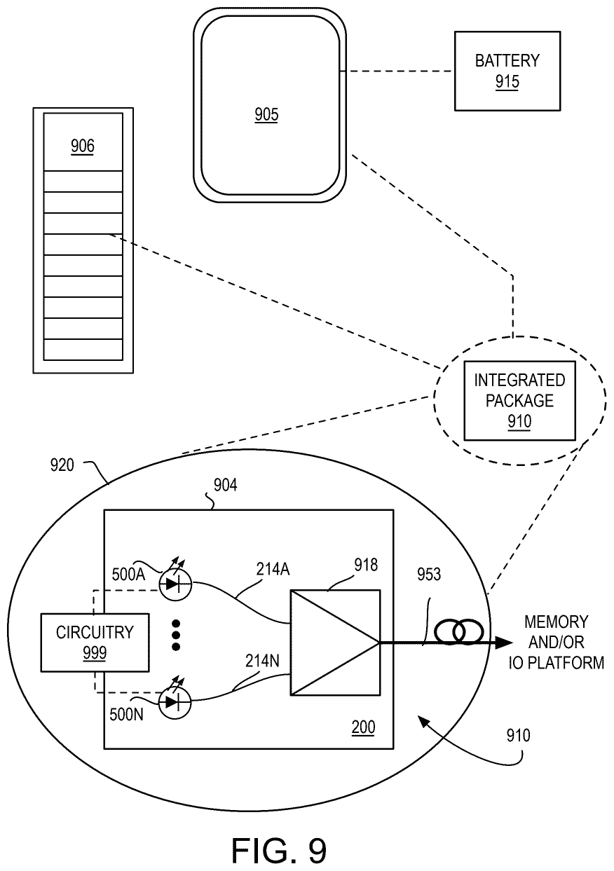

Active optical devices illustrated by the exemplary hybrid silicon structures described herein may be implemented in a wide variety of applications, systems, and platforms. FIG. 9 illustrates a mobile computing platform 905 and data server platform 906, each employing an optical link with one or more active hybrid silicon optical device structures comprising a high index spacer, for example as described elsewhere herein. Platform 906 may be any commercial server including any number of high-performance computing systems disposed within a rack and networked together for electronic data processing. The mobile platform 905 may be any portable device configured for each of electronic data display, electronic data processing, wireless electronic data transmission, or the like. For example, the platform 905 may be any of a tablet, a smart phone, laptop computer, etc., and may include an integrated or disintegrated package 910, and a battery power supply 915.

Platforms 905 or 906 may each include a PIC 904, illustrated in expanded view 920. PIC 904 may be one of a plurality of PICs in package 910, or a stand-alone packaged PIC. PIC 904 includes a silicon waveguide-coupled HSQDL structure comprising a high index spacer, in accordance with some embodiments. A plurality of wavelengths output by a plurality of HSQDL structures 500A-500N to a plurality of optical waveguides 214A-214N disposed on substrate 200 may be combined with an optical multiplexer 918 into wave division multiplexed (e.g., DWDM) optical beam. The optical beam may be coupled off-chip to an optical wire or fiber 953, for example through a top-side coupler or edge coupler. HSQDL structures 500A-500N are electrically coupled to integrated comb driver circuitry 999, which may for example further include a voltage supply. HSQDL structures 500A-500N may output at different center wavelengths (e.g., with 0.5-3.0 nm spacing). In certain embodiments, comb driver circuitry 999 is implemented with CMOS transistors also disposed on the substrate 200. In other embodiments, comb driver circuitry 999 is implemented with CMOS transistors external of PIC 904.

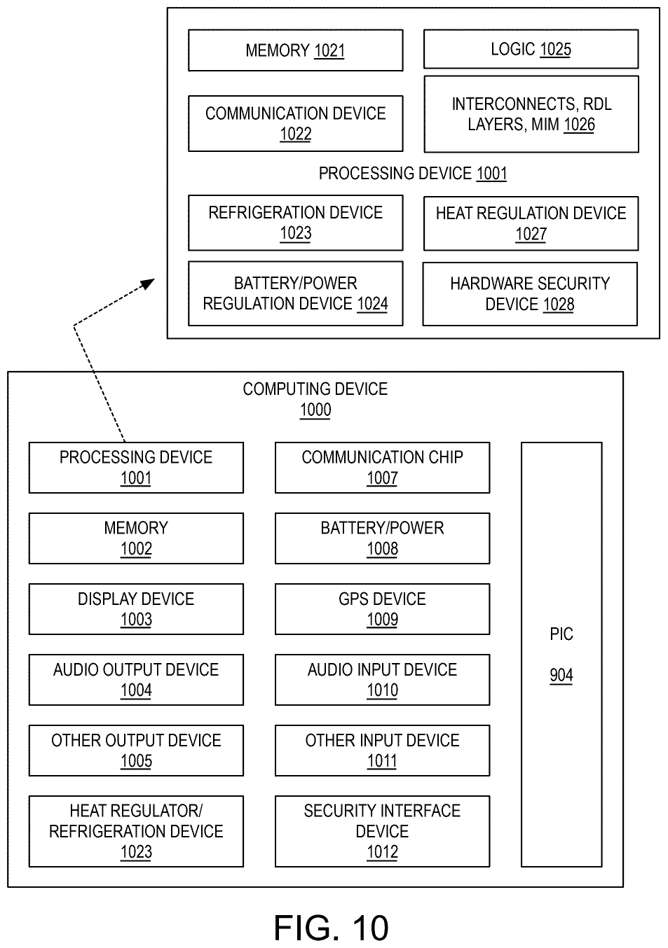

FIG. 10 is a block diagram of a cooled computing device 1000 in accordance with some embodiments. For example, one or more components of computing device 1000 may include any of the active hybrid silicon optical device structures discussed elsewhere herein. A number of components are illustrated in FIG. 10 as included in computing device 1000, but any one or more of these components may be omitted or duplicated, as suitable for the application. In some embodiments, some of the components included in computing device 1000 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1000 may not include one or more of the components illustrated in FIG. 10, but computing device 1000 may include interface circuitry for coupling to the one or more components. For example, computing device 1000 may not include memory 1002, but may include memory interface circuitry (e.g., a connector and driver circuitry) to which memory 1002 may be coupled.

Computing device 1000 may include a processing device 1001 (e.g., one or more processing devices). As used herein, the term processing device or processor indicates a device that processes electronic data from registers and/or memory to transform that electronic data into other electronic data that may be stored in registers and/or memory. Processing device 1001 may include a memory 1021, a communication device 1022, a refrigeration/active cooling device 1023, a battery/power regulation device 1024, logic 1025, interconnects 1026, a heat regulation device 1027, and a hardware security device 1028.

Processing device 1001 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1001 may include a memory 1021, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1001 shares a package with memory 1021. This memory may be used as cache memory and may include embedded dynamic random-access memory (eDRAM) or spin transfer torque magnetic random-access memory (STT-M RAM).

Computing device 1000 may include a heat regulation/refrigeration device 1023. Heat regulation/refrigeration device 1023 may maintain processing device 1001 (and/or other components of computing device 1000) at a predetermined low temperature during operation. This predetermined low temperature may be any temperature discussed elsewhere herein.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an optical data link comprising PIC 904 to transmit and/or receive optical communications through an optical multiplexed fiber, for example as described elsewhere herein.

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a global positioning system (GPS) device 1009 (or corresponding interface circuitry, as discussed above). GPS device 1009 may be in communication with a satellite-based system and may receive a location of computing device 1000, as known in the art.

Computing device 1000 may include another output device 1005 (or corresponding interface circuitry, as discussed above). Examples include an audio codec, a video codec, a printer, a wired or wireless transmitter for providing information to other devices, or an additional storage device.

Computing device 1000 may include another input device 1011 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, managing access lists, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that practice of the disclosed techniques and architectures is not limited to the embodiments so described but can be modified and altered without departing from the scope of the appended claims. For example, the above embodiments may include specific combinations of features as further provided below.

In first examples, an apparatus, comprises an optical waveguide comprising silicon. The apparatus comprises a plurality of III-V material layers over the optical waveguide. The III-V material layers comprise a III-V optical gain material between a p-type III-V layer and an n-type III-V layer. The apparatus comprises a first contact metallization in contact with the p-type III-V layer. The apparatus comprises a second contact metallization in contact with the n-type III-V material. An uppermost plane of the n-type III-V material is spaced from a top surface of the optical waveguide by at least 0.35 μm of III-V material.

In second examples, for any of the first examples a mesa structure comprising the p-type and optical gain layers is over the optical waveguide, the first contact metallization is on the mesa structure, the n-type III-V layer is under the mesa and over a top surface of the optical waveguide, and the second contact metallization is adjacent to the mesa and intersects the uppermost plane of the n-type III-V material.

In third examples, for any of the second examples the mesa structure is tapered along a longitudinal length of the optical waveguide to an end having a transverse lateral width of less than 0.4 μm.

In fourth examples, for any of the first through third examples the uppermost plane of the n-type III-V material is spaced from a top surface of the optical waveguide by no more than 0.7 m of III-V material.

In fifth examples, for any of the first through fourth examples the III-V material in direct contact with the top surface of the optical waveguide comprises n-type impurities and has a refractive index of the least 3.2.

In sixth examples, for any of the first through fifth examples the n-type III-V material is spaced apart from the top surface of the optical waveguide by an intervening III-V material layer having a different composition than the n-type III-V material.

In seventh examples, for any of the sixth examples the intervening III-V material has a donor impurity concentration that is at least two orders of magnitude lower than that of the n-type III-V material and wherein the intervening III-V material has a refractive index of at least 3.2

In eighth examples, for any of the sixth through seventh examples the intervening III-V material comprises at least one layer of InGaAsP or at least one layer of InAlAs.

In ninth examples, for any of the sixth through eighth examples the n-type III-V material has a thickness of less than 200 nm.

In tenth examples, for any of the fifth examples the III-V material in contract with the top surface of the optical waveguide comprises a layer of InGaAsP having a thickness of at least 0.35 μm.

In eleventh examples, for any of the first through tenth examples the optical waveguide is crystalline silicon and has a width less than 1 μm, and a largest transverse width of the mesa is at least 10 μm.

In twelfth examples, a photonic integrated circuit (PIC) comprises a silicon optical waveguide extending over a crystalline silicon substrate, and a hybrid silicon III-V laser (HSL) coupled to the silicon optical waveguide. The HSL comprises a plurality of III-V material layers over the silicon optical waveguide. The III-V material layers comprise a III-V optical gain material between a p-type III-V layer and an n-type III-V layer. The HSL comprises a first contact metallization in contact with the p-type III-V layer and a second contact metallization in contact with the n-type III-V material. The HSL comprises a thickness of III-V material between the III-V optical gain material and the silicon optical waveguide to support a resonant optical mode having a peak power located at least 0.25 um below the III-V gain material.

In thirteenth examples, for any of the twelfth examples the thickness of III-V material between the III-V optical gain material and the silicon optical waveguide is to confine a resonant optical mode having an effective mode area of at least 3.0 μm².

In fourteenth examples, for any of the twelfth through thirteenth examples the thickness of III-V material between the III-V optical gain material and the silicon optical waveguide is at least 0.6 μm.

In fifteenth examples, for any of the fourteenth examples the thickness of III-V material between the III-V optical gain material and the silicon optical waveguide comprises an n-type III-V material layer having a refractive index of at least 3.2 and a thickness of at least 0.3 μm.

In sixteenth examples, for any of the fifteenth examples the III-V material between the III-V optical gain material and the silicon optical waveguide has a thickness of 0.4-0.6 μm.

In seventeenth examples, for any of the fifteenth through sixteenth examples the III-V material between the III-V optical gain material and the silicon optical waveguide comprises donor impurities.

In eighteenth examples, for any of the fifteenth through seventeenth examples the n-type III-V material comprises a layer of InGaAsP and wherein the silicon optical waveguide is monocrystalline and has a width less than 1 μm.

In nineteenth examples, a method comprises supplying power a photonic integrated circuit (PIC), wherein the PIC comprises a silicon optical waveguide extending over a crystalline silicon substrate and a hybrid silicon III-V laser (HSL) coupled to the silicon optical waveguide. The HSL comprises a plurality of III-V material layers over the silicon optical waveguide. The III-V material layers comprise a III-V optical gain material between a p-type III-V layer and an n-type III-V layer. Supplying the power further comprises coupling a first power supply rail to a first contact metallization in contact with the p-type III-V layer, and coupling a second power supply rail to a second contact metallization in contact with the n-type III-V material, and generating a resonant optical mode within the HSL. The resonant optical mode having a peak power located at least 0.25 um below the III-V gain material.

In twentieth examples, for any of the nineteenth examples the resonant optical mode has an effective mode area of at least 3.0 μm².

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosed techniques and architectures should therefore be determined with reference to the appended claims, along with the full scope of equivalents to which such claims are entitled.

What is claimed is:

1. An apparatus, comprising:
an optical waveguide comprising silicon;
a plurality of III-V material layers over the optical waveguide, wherein the III-V material layers comprise a III-V optical gain material between a p-type III-V layer and an n-type III-V layer;
a first contact metallization in contact with the p-type III-V layer; and
a second contact metallization in contact with the n-type III-V material, wherein an uppermost plane of the n-type III-V material is spaced from a top surface of the optical waveguide by at least 0.35 μm of III-V material.

2. The apparatus of claim 1, wherein
a mesa structure comprising the p-type and optical gain layers is over the optical waveguide;
the first contact metallization is on the mesa structure;
the n-type III-V layer is under the mesa and over a top surface of the optical waveguide; and
the second contact metallization is adjacent to the mesa and intersects the uppermost plane of the n-type III-V material.

3. The apparatus of claim 2, wherein the mesa structure is tapered along a longitudinal length of the optical waveguide to an end having a transverse lateral width of less that 0.4 km.

4. The apparatus of claim 1, wherein the uppermost plane of the n-type III-V material is spaced from a top surface of the optical waveguide by no more than 0.7 μm of III-V material.

5. The apparatus of claim 1, wherein III-V material in direct contact with the top surface of the optical waveguide comprises donor impurities and has a refractive index of at least 3.2.

6. The apparatus of claim 1, wherein the n-type III-V material is spaced apart from the top surface of the optical waveguide by an intervening III-V material layer having a different composition than the n-type III-V material and has a refractive index of at least 3.2.

7. The apparatus of claim 6, wherein the intervening III-V material has a donor impurity concentration that is at least two orders of magnitude lower than that of the n-type III-V material.

8. The apparatus of claim 6, wherein the intervening III-V material comprises at least one layer of InGaAsP or at least one layer of InAlAs.

9. The apparatus of claim 6, wherein the n-type III-V material has a thickness of less than 200 nm.

10. The apparatus of claim 5, wherein the III-V material in contract with the top surface of the optical waveguide comprises a layer of InGaAsP having a thickness of at least 0.35 μm.

11. The apparatus of claim 1, wherein:
the optical waveguide is crystalline silicon and has a width less than 1 m; and
a largest transverse width of the mesa is at least 10 μm.

12. A photonic integrated circuit (PIC), comprising:
a silicon optical waveguide extending over a crystalline silicon substrate; and
a hybrid silicon III-V laser (HSL) coupled to the silicon optical waveguide, wherein the HSL comprises:
a plurality of III-V material layers over the silicon optical waveguide, wherein the III-V material layers comprise a III-V optical gain material between a p-type III-V layer and an n-type III-V layer;
a first contact metallization in contact with the p-type III-V layer; and
a second contact metallization in contact with the n-type III-V material, wherein the HSL comprises a thickness of III-V material between the III-V optical gain material and the silicon optical waveguide to support a resonant optical mode having a peak power located at least 0.25 um below the III-V gain material.

13. The PIC of claim 12, wherein the thickness of III-V material between the III-V optical gain material and the silicon optical waveguide is to confine a resonant optical mode having an effective mode area of at least 3.0 μm².

14. The PIC of claim 12, wherein the thickness of III-V material between the III-V optical gain material and the silicon optical waveguide is at least 0.6 μm.

15. The PIC of claim 14, wherein the thickness of III-V material between the III-V optical gain material and the silicon optical waveguide comprises an n-type III-V material layer having a refractive index of at least 3.2 and a thickness of at least 0.3 μm.

16. The PIC of claim 15, wherein the III-V material between the III-V optical gain material and the silicon optical waveguide has a thickness of 0.4-0.6 μm.

17. The PIC of claim 15, wherein the III-V material between the III-V optical gain material and the silicon optical waveguide comprises donor impurities.

18. The PIC of claim 15, wherein the n-type III-V material comprises a layer of InGaAsP and wherein the silicon optical waveguide is monocrystalline and has a width less than 1 μm.

19. A method comprising:
supplying power a photonic integrated circuit (PIC), wherein the PIC comprises:
a silicon optical waveguide extending over a crystalline silicon substrate; and
a hybrid silicon III-V laser (HSL) coupled to the silicon optical waveguide, wherein the HSL comprises:
a plurality of III-V material layers over the silicon optical waveguide, wherein the III-V material layers comprise a III-V optical gain material between a p-type III-V layer and an n-type III-V layer;
and wherein supplying the power further comprises:
coupling a first power supply rail to a first contact metallization in contact with the p-type III-V layer; and
coupling a second power supply rail to a second contact metallization in contact with the n-type III-V material; and
generating a resonant optical mode within the HSL, the resonant optical mode having a peak power located at least 0.25 um below the III-V gain material.

20. The method of claim 19, wherein the resonant optical mode has an effective mode area of at least 3.0 μm².
